(19) United States
(12) Patent Application Publication
(10) Pub. No.: US 2008/0075200 A1
(43) Pub. Date: Mar. 27, 2008

(54) Detecting circuit, modulation scheme identifying circuit, integrated circuit, tuning device, and common multi-scheme receiving device

(75) Inventor: Kensuke Baba, Osaka (JP)

Correspondence Address: BIRCH STEWART KOLASCH & BIRCH, PO BOX 747, FALLS CHURCH, VA, 22040-0747, US

(73) Assignee: SHARP KABUSHIKI KAISHA

(21) Appl. No.: 11/882,430

(22) Filed: Aug. 1, 2007

(30) Foreign Application Priority Data
Sep. 25, 2006 (JP) 2006-259132

(51) Int. Cl. H03D 1/00; H04L 25/08; H04L 27/00

(52) U.S. Cl. 375/317; 375/320; 375/325

(57) ABSTRACT

A plurality of detectors are included which have different detection frequencies. The detectors detect the signal level of an IF signal at the respective detection frequencies. The IF signal is produced by frequency conversion of an incoming signal in a mixing section. A comparator identifies the modulation scheme of the incoming signal from a comparison of the signal levels detected by the detectors. Accordingly, a detecting circuit is realized which is contained in a common multi-scheme receiver receiving a plurality of transmission signals with different modulation schemes and which identifies various modulation schemes for incoming signals.

This nonprovisional application claims priority under 35 U.S.C. § 119(a) on Patent Application No. 2006-259132 filed in Japan on 25, Sep. 2006, the entire contents of which are hereby incorporated by reference.

### FIELD OF THE INVENTION

The present invention relates to detecting circuits, mounted to common multi-scheme receivers capable of receiving a plurality of transmission signals with different modulation schemes, which identify the modulation scheme of an incoming signal, and also to integrated circuits, modulation scheme identifying circuits, tuning devices, and common multi-scheme receivers which contain such a detecting circuit.

### BACKGROUND OF THE INVENTION

Common multi-scheme receiving devices have been used which is capable of receiving a plurality of transmission signals with different modulation schemes. As an example, in Japanese terrestrial television broadcasting, AM (Amplitude Modulation) and FM (Frequency Modulation) analog broadcasts and an OFDM (Orthogonal Frequency Division Multiplex) digital broadcast are carried out for each channel in each channel frequency band. In cable television broadcasting, a plurality of signals with different modulation schemes are transmitted together as in the preceding case.

To receive these broadcasts with different modulation schemes with a common receiving device, the device needs to contain signal demodulating circuits for the individual modulation schemes and thus be compatible with the multiple schemes. The following will describe operation principles of the common multi-scheme receiving device.

FIG. 5 is a block diagram schematically illustrating the structure of the common multi-scheme receiving device. The common multi-scheme receiving device in the figure includes a receiver antenna 1, an input tuning circuit 2, a high frequency amplifying circuit 3, an interstage tuning circuit 4, a mixing section 20, and demodulating circuits 12, 13. The mixing section 20 includes a mixing circuit 5 and a local oscillating circuit 6. The demodulating circuits 12, 13 demodulate signals with different modulation schemes. Assume here that the demodulating circuit 12 demodulates analog broadcasts (AM and FM) and that the demodulating circuit 13 demodulates a digital broadcast (OFDM modulation scheme).

The receiver antenna 1 receives a multi-channel signal, each channel modulated by a different scheme, (for example, a single signal carrying both analog and digital broadcasts) and feeds the signal to the input tuning circuit 2. The input tuning circuit 2 derives only a desired signal component from the incoming multi-channel signal for output to the high frequency amplifying circuit 3.

The high frequency amplifying circuit 3 amplifies the signal fed from the input tuning circuit 2 for output to the interstage tuning circuit 4.

The interstage tuning circuit 4 removes unnecessary components from the signal fed from the input tuning circuit 2 for output to the mixing circuit 5.

The mixing section 20 mixes the signal fed from the interstage tuning circuit 4 to the mixing circuit 5 with a local oscillation component generated in the local oscillating circuit 6. Thus, the section 20 lowers the frequency of the signal to produce an IF (intermediate frequency) signal. The resultant IF signal (IFout) is output to the demodulating circuits 12 and 13 from the output terminal (not shown) of the mixing section.

The demodulating circuits 12, 13 receive, from external control means (not shown), an external control input signal that is in accordance with a modulation scheme select command from a user. One of the demodulating circuits 12, 13 is selected as their activation is controlled through the external control input signal. The selected demodulating circuit demodulates the IF signal output of the mixing section 20. After the demodulation in the demodulating circuit, the signal is supplied to another circuit for video/audio processing. The above process selects and demodulates a desired incoming signal from the incoming signals involving a plurality of modulation schemes.

The methods of selecting a demodulating circuit in accordance with the modulation scheme of the desired incoming signal are divided into the three major categories below:

### A) No particular demodulating circuit is selected.

### B) A demodulating circuit is selected by the end user (see FIG. 5).

### C) A demodulating circuit is selected through signal detection.

### Methods A, B raise the following problems.

According to method A, all demodulating circuits are kept turned on to receive a plurality of modulated signals. Those demodulating circuit(s) which are not receiving a signal are wasting power. What is worse, they generate unnecessary interference signals.

Method B requires the user to, for example, select either analog broadcast or digital broadcast in selecting a broadcast channel on a remote controller. To do that, the user needs to know in advance whether the desired channel is an analog broadcast or a digital broadcast. Moreover, the process requires the user to manually input his/her selection.

Method C involves, for example, the detection of a horizontal synchronization signal by an analog demodulating circuit. This particular example, however, requires the analog demodulating circuit to stay activated. That translates into unnecessary power consumption during reception of digital broadcast. Also, the activation of the analog demodulating circuit instigates undesirable interference signals.

For example, Japanese Unexamined Patent Publication 5-347736/1993 (Tokukaihei 5-347736; published Dec. 27, 1993) discloses a technique that distinguishes reception of an analog modulated wave from reception of a digital modulated wave by means of the presence/absence of a signal which appears as an output of a demodulating means if the incoming signal is a digital modulated wave (synchronous word which is multiplexed in digital signals). The technique requires the digital demodulating circuit to stay activated, which translates into unnecessary power consumption during reception of analog broadcast.

Accordingly, there is a demand for technology, addressing these problems, which automatically identifies modulation schemes without relying on the detection by the demodulating circuit.

Japanese Unexamined Patent Publication (Tokukai) 2001-285752 (published Oct. 12, 2001), cited here as an example, discloses a technique used in multi-scheme terrestrial broadcast receiving devices compatible with digital modulated wave broadcast and NTSC (National Television System Committee) analog modulated wave broadcast. The technique distinguishes an analog modulated wave and a digital modulated wave according to the carrier component for an analog NTSC modulated wave derived from an IF signal produced by frequency conversion of a selected high-frequency signal. Tokukai 2001-285752 also discloses a technique used in multi-scheme receiving devices compatible with QAM (Quadrature Amplitude Modulation) digital cable broadcast and multi-value VSB (Vestigial Sideband) modulated digital terrestrial broadcast. The technique distinguishes a QAM wave and a multi-value VSB digital modulated wave according to a pilot wave component for a multi-value VSB modulated wave derived from an IF signal produced by frequency conversion of a selected high-frequency signal.

Japanese Unexamined Patent Publication 7-143021/1995 (Tokukaihei 7-143021; published Jun. 2, 1995) discloses a technique used in modulation scheme identifying circuits which distinguish a spread spectrum modulation scheme and a vestigial carrier modulation scheme. The technique lowers the frequency of the incoming signal to a low-frequency signal (for example, an IF signal) and detects power across the signal bandwidth and near the carrier frequency for the low-frequency signal. The technique identifies the modulation schemes according to the ratio of the amplitudes of the detection signals.

Japanese Unexamined Patent Publication (Tokukai) 2006-80757 (published Mar. 23, 2006) discloses a technique used in receiving devices which receive frequency-multiplexed digital broadcast of a digital broadcast signal modulated by a first modulation scheme and a digital broadcast signal modulated by a second modulation scheme. The technique identifies the modulation schemes according to the frequencies of the intermediate frequency signal.

The Tokukai 2001-285752 technique causes some problems. The technique amplifies the IF signal, or tuner output, in an amplifier. The amplified IF signal is used to identify the modulation schemes. The inclusion of the amplifier is essential. Also, the tuner needs to be placed separately from the modulation scheme identifying circuit. These factors add to circuit size. The use of the amplified IF signal in distinguishing modulation schemes adds to the power consumption by the identifying circuit. Furthermore, the Tokukai 2001-285752 technique is applicable only to multi-scheme terrestrial broadcast receiving devices for digital modulated wave broadcast and NTSC analog modulated wave broadcast and multi-scheme receiving devices for QAM digital cable broadcast and multi-value VSB modulated digital terrestrial broadcast.

The Tokukaihei 7-143021 technique can distinguish only a spread spectrum modulation scheme and a vestigial carrier modulation scheme. Also, the Tokukaihei 7-143021 technique identifies the modulation schemes after frequency cutoff of the IF signal with a lowpass filter. Therefore, if the frequency of the picture carrier on the analog modulated signal is lower than the center frequency of the digital modulated signal (especially, if the carrier frequency largely differs from the center frequency), the signal component which should be detected is removed by the lowpass filter. That greatly lowers the accuracy in the modulation scheme identification.

The Tokukai 2006-80757 technique converts the IF signal output of the tuner from analog to digital. The A/D converted IF signal is used to identify the modulation schemes. The inclusion of an A/D converter is essential. Also, the tuner needs to be placed separately from the modulation scheme identifying circuit. These factors add to circuit size. The Tokukai 2006-80757 technique can distinguish only digital modulation schemes which use different frequency band.

### SUMMARY OF THE INVENTION

The present invention, conceived to address these problems, has objective of providing a detecting circuit, mounted to a common multi-scheme receiving device which receives a plurality of transmission signals with different modulation schemes, which is capable of distinguishing various modulation schemes and identifying the modulation scheme of an incoming signal.

Another objective of the present invention is to reduce the size of the integrated circuit, the tuning device, and the common multi-scheme receiving device which contain the detecting circuit capable of automatically identifying the modulation scheme of an incoming signal.

The detecting circuit of the present invention is, to solve the problems, characterized in that it is contained in a common multi-scheme receiver for receiving a plurality of transmission signals with different modulation schemes, the detecting circuit identifying a modulation scheme of an incoming signal from an IF signal produced by frequency conversion of the incoming signal, the detecting circuit including: detectors having different detection frequencies, each detector detecting a signal level of the IF signal at the detection frequency thereof; and a comparator for identifying the modulation scheme of the incoming signal from the signal levels detected by the detectors.

According to the configuration, the detectors detect the signal level at different detection frequencies. The comparator identifies the modulation scheme of the incoming signal from a comparison of the detected signal levels. Accordingly, various modulation schemes are identified by simply setting the detection frequencies of the detectors in accordance with the modulation schemes of incoming signals.

The modulation scheme identifying circuit of the present invention is, to solve the problems, characterized in that it is used in a common multi-scheme receiving device for receiving a plurality of transmission signals with different modulation schemes, the modulation scheme identifying circuit including: a mixing section for converting an incoming signal to an IF signal; and a detecting circuit, connected to the mixing section, for identifying a modulation scheme of the incoming signal from the IF signal output of the mixing section.

According to the configuration, the detecting circuit is connected to the mixing section. The configuration enables the modulation scheme identification in a relatively early stage in the signal path when compared with a conventional configuration in which the output of the mixing section is amplified before being fed to the detecting circuit and another conventional configuration in which the output of the mixing section is filtered before being fed to the detecting circuit. These factors allow for reduction in circuit size and power consumption. In addition, the IF signal output of the mixing section is fed directly to the detecting circuit where a modulation scheme identification is carried out. That configuration reduces the power consumption by the detecting circuit over conventional configurations in which the IF signal output of the mixing section is amplified before the modulation scheme identification is carried out.

Additional objects, advantages and novel features of the invention will be set forth in part in the description which follows, and in part will become apparent to those skilled in the art upon examination of the following or may be learned by practice of the invention.

### BRIEF DESCRIPTION OF THE DRAWINGS

FIG. 1 is a circuit block diagram illustrating an exemplary structure for the common multi-scheme receiving device of an embodiment of the present invention.

FIG. 2 is a circuit block diagram illustrating another exemplary structure for the common multi-scheme receiving device of an embodiment of the present invention.

FIG. 3(a) is a graph representing a modulated signal spectrum specified in a terrestrial analog broadcast standard.

FIG. 3(b) is a graph representing a modulated signal spectrum specified in a terrestrial digital broadcast standard.

FIG. 4(a) is a graph representing a signal level difference in a frequency band in the spectrum shown in FIG. 3(a).

FIG. 4(b) is a graph representing a signal level difference in a frequency band in the spectrum shown in FIG. 3(b).

FIG. 5 is a circuit block diagram illustrating the structure of a conventional common multi-scheme receiving device.

### DESCRIPTION OF THE EMBODIMENTS

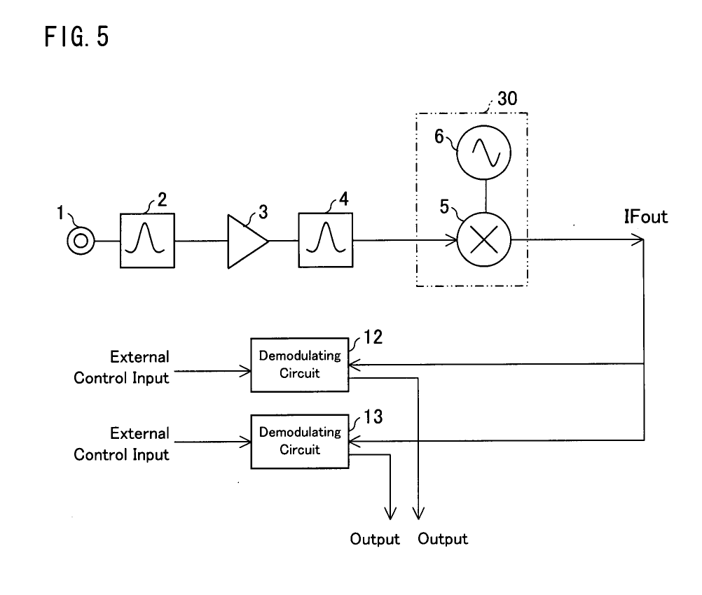

The following will describe embodiments of the present invention in reference to the figures. Here, for convenience, the members that have the same arrangement and function as those shown in FIG. 5 are indicated by the same reference numerals and their description may be entirely or partly omitted.

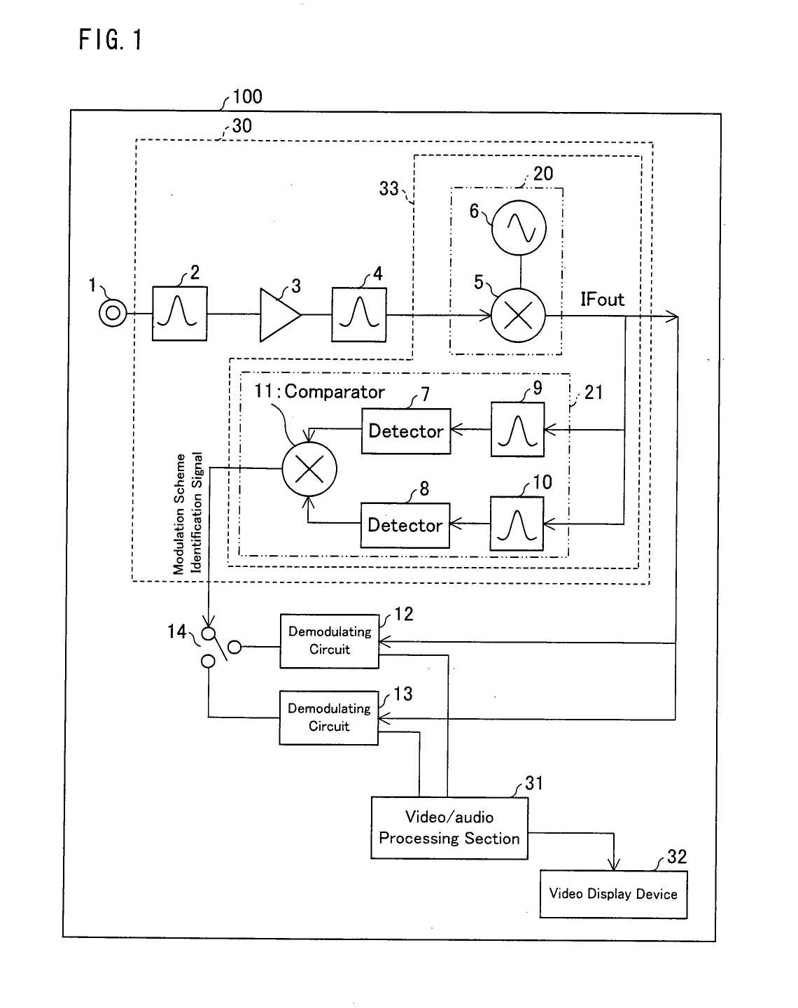

FIG. 1 is a block diagram illustrating the structure of a detecting circuit in a common multi-scheme receiving device 100 in accordance with the present embodiment. The common multi-scheme receiving device 100 shown is a television broadcast receiving device which receives terrestrial digital broadcast and terrestrial analog broadcast to produce video and audio outputs.

As shown in the figure, the common multi-scheme receiving device 100 contains a receiver antenna 1, a tuning device 30, demodulating circuits 12, 13, a control circuit 14, a video/audio processing circuit 31, and a video display device 32. The tuning device 30 contains an input tuning circuit 2, a high frequency amplifying circuit 3, an interstage tuning circuit 4, a mixing section 20, and a detecting circuit 21.

The receiver antenna 1 receives a multi-channel signal, each channel modulated by a different scheme, (for example, a single signal carrying both analog and digital broadcasts) for output to the input tuning circuit 2 in the tuning device 30.

The input tuning circuit 2 derives only a desired signal component from the incoming multi-channel signal for output to the high frequency amplifying circuit 3.

The high frequency amplifying circuit 3 amplifies the signal fed from the input tuning circuit 2 for output to the interstage tuning circuit 4.

The interstage tuning circuit 4 removes unnecessary components from the signal fed from the input tuning circuit 2 for output to a mixing circuit 5.

The mixing section 20 contains the mixing circuit 5 and a local oscillating circuit 6. The mixing section 20 mixes the signal fed from the interstage tuning circuit 4 to the mixing circuit 5 with a local oscillation component generated in the local oscillating circuit 6. Thus, the section 20 lowers the frequency of the signal to produce an IF (intermediate frequency) signal. The resultant IF signal (IFout) is output to the demodulating circuits 12 and 13 and the detecting circuit 21.

The detecting circuit 21 identifies the modulation scheme of the received signal according to the IF signal of the received signal fed from the mixing section 20 and outputs a result-indicating identification output signal to the control circuit 14. Details of the detecting circuit 21 will be given later. As indicated by a broken line in FIG. 1, the modulation scheme identifying circuit 33 is composed of the mixing section 20 and the detecting circuit 21. The modulation scheme identifying circuit 33 may be provided as a complex IC (integrated circuit) on a common substrate. If the modulation scheme identifying circuit 33 is provided as a complex IC, the detecting circuit 21 becomes more compact and cheaper.

The control circuit 14 turns on power supply from the power supply means (not shown) designated for a particular demodulating circuit which is capable of the modulation scheme of the received signal and turns off the power supply from all the power supply means for the other demodulating circuits, in accordance with the identification output signal output of the detecting circuit 21. The control circuit 14 may, for example, have functions of switching between RF-AGC feedback loops for RF signal gain control and/or if the demodulating circuit is preceded by an amplifying circuit, of controlling the operation of the amplifying circuit.

The demodulating circuits 12, 13 demodulate the IF signal output of the mixing section 20 for output to the video/audio processing circuit 31. The demodulating circuits 12, 13 demodulate signals modulated by different modulation schemes. In the present embodiment, the demodulating circuit 12 demodulates analog broadcasts (AM and FM), whilst the demodulating circuit 13 demodulates a digital broadcast (OFDM modulation scheme). As mentioned above, the control circuit 14 turns on the demodulating circuit which corresponds to the modulation scheme of the received signal and turns off the other demodulating circuit. The present embodiment assumes that there are provided two demodulating circuits. This is not however only the possibility. There may be provided, for example, three or more of them in accordance with the modulation schemes of signals to be received.

The video/audio processing circuit 31 carries out predetermined processes on the video and audio signals contained in the signal demodulated in by the demodulating circuits 12, 13 for output to the video display device 32.

In the video display device 32, an image display section outputs an image display from a video signal output of the video/audio processing circuit 31, and an audio output section, such as speakers, outputs sounds from an audio signal output of the video/audio processing circuit 31. The display scheme of the image display section is not limited in any particular manner The image display section may be any publicly known video display device. Examples include a liquid crystal display, a plasma display, a CRT, and an organic LED display, as well as large varieties of other video display devices.

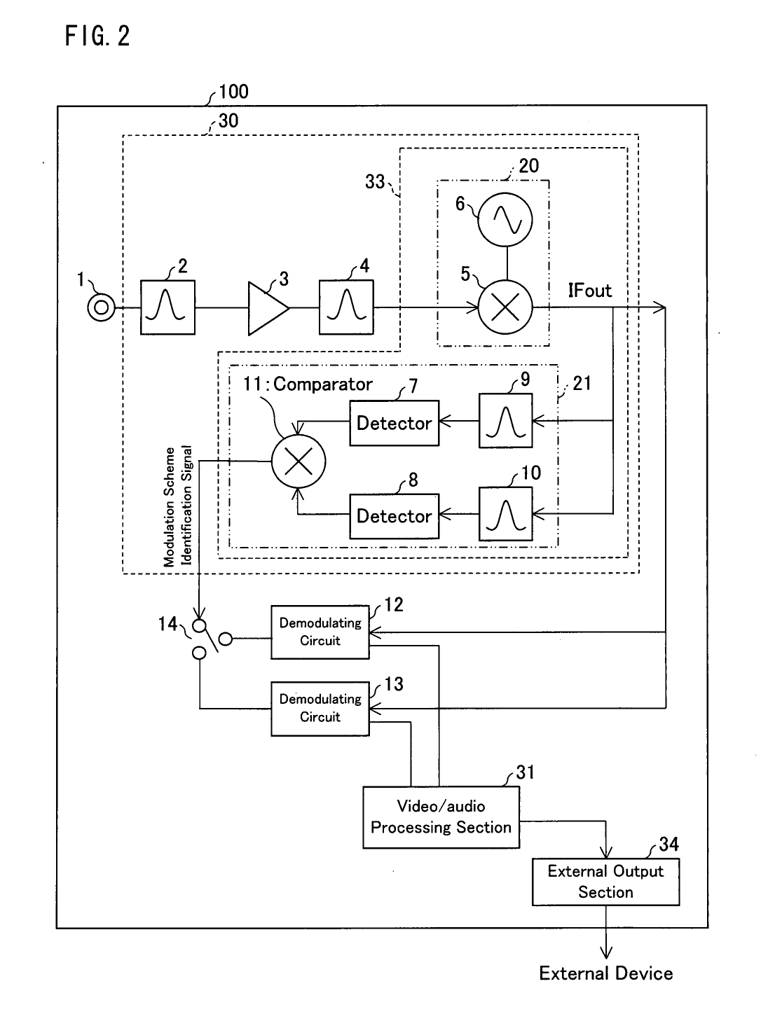

The common multi-scheme receiving device 100 does not necessarily include the video display device 32. As an example, the device 100 may include an external output section 34 which, as shown in FIG. 2, outputs signal outputs (video and audio signals) of the video/audio output section 31 to an external device over wired or wireless transmission. This is a configuration of a “set-top box.”

Next, the detecting circuit 21 will be described. Referring to FIG. 1, the detecting circuit 21 contains detectors 7, 8, filter circuits 9, 10, and a comparator 11.

The filter circuits 9, 10 are connected to the output terminal (not shown) of the mixing section 20. The filter circuits 9, 10 respectively remove frequency components other than the detection frequencies of the detectors 7, 8 from the IF signal output of the mixing section 20. The filter circuit 9 passes signal components at frequencies near the detection frequency of the detector 7 and rejects those at other frequencies. Similarly, the filter circuit 10 passes signal components at frequencies near the detection frequency of the detector 8 and rejects those at other frequencies.

The detectors 7, 8 detect a signal level at the predetermined detection frequency in the IF signal outputs of the filter circuits 9, 10, to output detection results to the comparator 11. The detection frequencies of the detectors 7, 8 are set in advance in accordance with the modulation schemes of incoming signals. The detection frequency setting for the detectors 7, 8 will be detailed later.

The detectors 7, 8 need only to detect IF signal intensity (signal level) at the respective detection frequencies to which they are calibrated. Any detectors of various publicly known ones may be used. For example, the detectors 7, 8 may be those which detect the amplitude of an input signal waveform. In addition, the detectors 7, 8 may have the same structure other than their having different detection frequencies.

The comparator 11 compares the detection result from the detector 7 with the detection result from the detector 8, identifies the modulation scheme of the incoming signal based on the comparison, and outputs a result of the identifying as a modulation scheme identifying signal.

For example, the comparator 11 determines a difference between the detection result from the detector 7 (the signal level at the detection frequency of the detector 7) and the detection result from the detector 8 (the signal level at the detection frequency of the detector 8). Then, the comparator 11 identifies a modulation scheme by determining whether the difference is greater than a preset reference value (threshold). The modulation scheme identifying signal may be a logic signal. For example, when the difference greater than the reference value, the comparator 11 determines that it is an analog modulation scheme and outputs a HIGH level signal; when the difference is smaller than the reference value, the comparator 11 determines that it is a digital modulation scheme and outputs a LOW level signal.

The reference value may be determined appropriately depending on the modulation scheme of the incoming signal.

Now, the detection frequency setting for the detectors 7, 8 will be described. The detection frequencies of the detectors 7, 8 are set according to a frequency distribution for the modulation scheme of an incoming signal (modulated signal).

The description here will focus, as an example, on discriminating between analog and digital broadcast modulation schemes used in the Japanese television broadcasting system.

The current Japanese broadcasting system employs two schemes: AM video and FM audio for terrestrial analog broadcast and OFDM modulation for terrestrial digital broadcast.

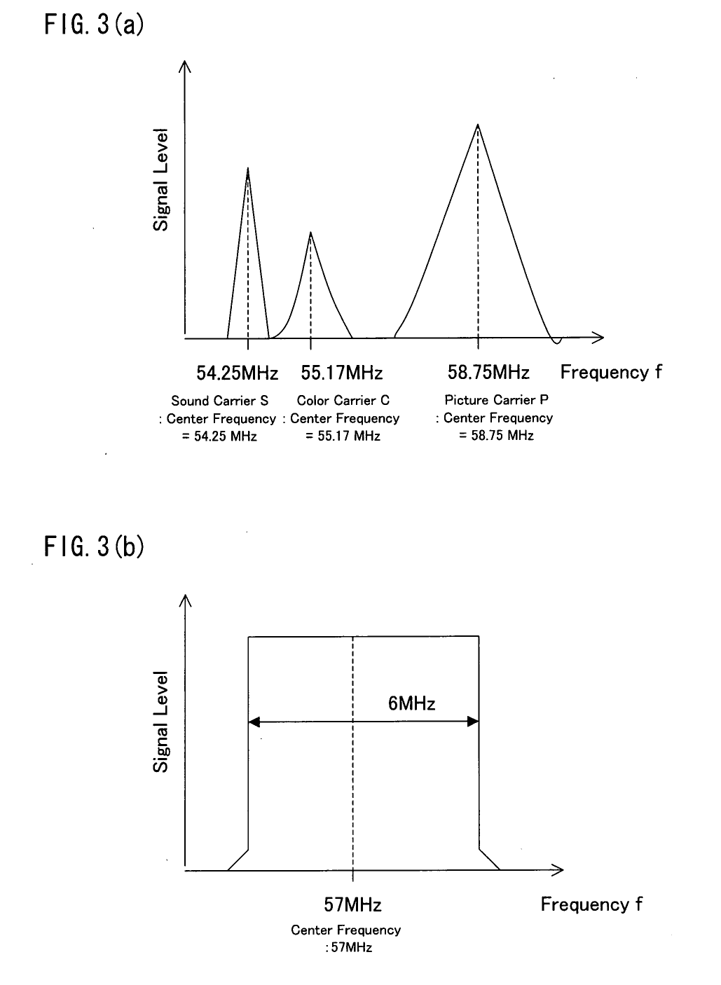

FIG. 3(a) is a graph representing modulated signal spectra for terrestrial analog broadcast. FIG. 3(b) is a graph representing a modulated signal spectrum for terrestrial digital broadcast. In other words, FIGS. 3(a) and 3(b) represent a signal level distribution across frequencies of the IF signal produced in the mixing section 20 by frequency-converting the received terrestrial analog and digital signals.

Referring to FIG. 3(a), the spectrum of the terrestrial analog scheme includes a picture carrier (P: Center Frequency=58.75 MHz), a color carrier (C: Center Frequency=55.17 MHz), and a sound carrier (S: Center Frequency=54.25 MHz).

Now, referring to FIG. 3(b), the terrestrial digital broadcast employs an OFDM modulation scheme which uses 5460 carriers (carriers) across the 6-MHz bandwidth of each channel. Therefore, with the peak values of individual carriers being smoothed out, there appears a spectrum with a center frequency of 57 MHz and a bandwidth of 6 MHz which is flat substantially across that bandwidth.

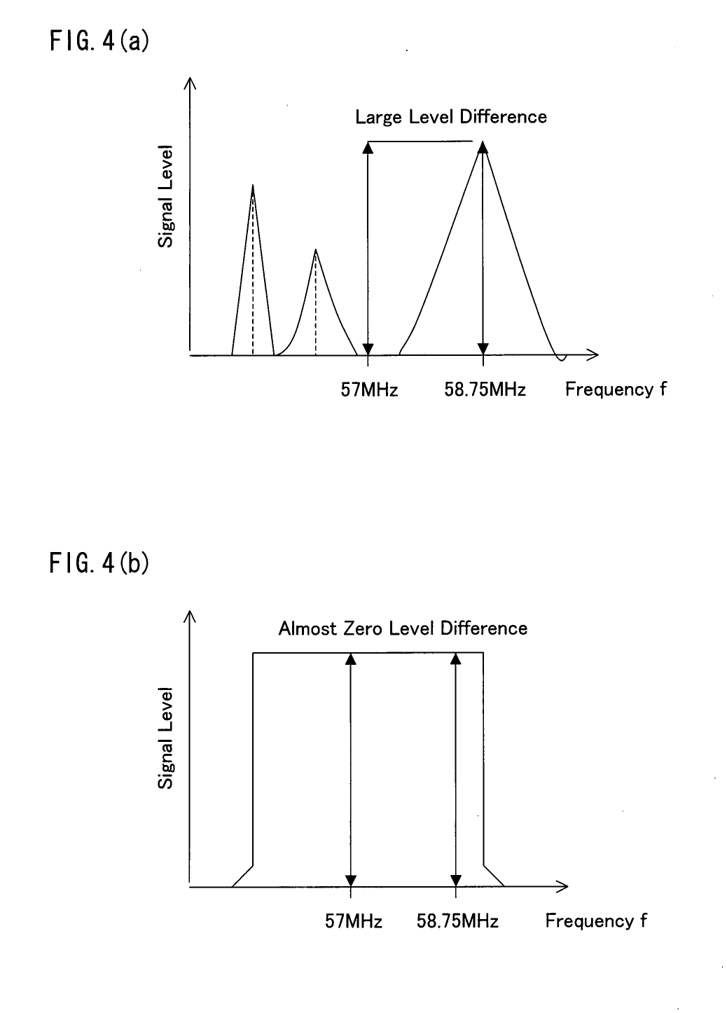

A comparison of the frequency distribution of the terrestrial analog scheme to that of the terrestrial digital scheme shows that for the terrestrial digital scheme, there is little difference in signal level in the 6-MHz bandwidth as shown in FIG. 4(b). In contrast, for the terrestrial analog scheme, the signal level peaks at the center frequencies of the sound, color, and picture carriers (54.25 MHz, 55.17 MHz, 58.75 MHz) and drops to very low values at frequencies between these center frequencies (for example, the signal level is 0 at 57 MHz as shown in FIG. 4(a))

Thus, as an example, compare the signal level difference between 58.75 MHz and 57 MHz for the terrestrial analog broadcast and for the terrestrial digital broadcast. The comparison illustrates a very small difference for the terrestrial digital broadcast (signal level difference ≈0) and a very large difference for the terrestrial analog broadcast.

Accordingly, the detecting circuit 21 of the present embodiment is adapted to distinguish the modulation schemes of incoming signals based on the signal level difference between 58.75 MHz and 57 MHz.

Specifically, the detection frequency of the detector 7 is set to 57 MHz, and the detection frequency of the detector 8 is set to 58.75 MHz. In addition, The detectors 7, 8 are immediately preceded by the filter circuits 9, 10 which restrict the frequencies of the IF signal output of the mixing section 20 to near the respective detection frequencies of the respective detectors 7, 8. The comparator 11 compares the difference between the signal level detected by the detector 8 and the signal level detected by the detector 7 to a preset threshold (reference value, comparison threshold). The comparator 11 outputs to the control circuit 14 a modulation scheme identifying signal indicative of a terrestrial digital signal if the difference is below the threshold and a modulation scheme identifying signal indicative of a terrestrial analog signal if the difference is more than or equal to the threshold.

The filter circuits 9, 10 preferably have a narrow passband and sharp cutoffs for a well-focused signal spectrum and hence improved accuracy in the modulation scheme identification. Concretely, each of the filter circuits 9, 10 preferably has a cutoff level (for example, 6 db or greater) exceeding the threshold in a 3.5-MHz bandwidth (not exceeding twice the difference between the detection frequencies of the detectors) with a center frequency which is equal to the detection frequency of the detector immediately following the filter circuit. This setup prevents the signal at the detection frequency of one of the detectors from affecting the detection of a signal level by the other detector, thereby achieving accurate modulation scheme identification.

The detection frequencies of the detectors do not need to be set precisely to the abovementioned detection frequencies (57 MHz, 58.75 MHz). The detection frequencies of the detectors 7, 8 may be set to suitable values in accordance with the filtering properties of the filter circuits 9, 10. For example, if the filter circuits 9, 10 are bandpass filters with passband=center frequency±1.5 MHz, the tolerance range for the detection frequency of the detector 7 is 57±0.75 MHz, and the tolerance range for the detection frequency of the detector 8 is 58.75 MHz±0.75 MHz. The detectors 7, 8, set up within these tolerance ranges, are able to distinguish the modulation schemes with sufficient reliability.

As described in the foregoing, the detecting circuit 21 of the present embodiment includes the detectors 7, 8 with different detection frequencies. The detectors 7, 8 detect, at the respective detection frequencies, the level of the IF signal produced by frequency conversion of a received signal in the mixing section 20. Based on the comparison of the signal levels detected by the detectors 7, 8, the comparator 11 identifies the modulation scheme of the incoming signal.

Accordingly, various modulation schemes can be distinguished by simply setting the detection frequencies of the detectors in accordance with the modulation schemes of received signals.

In the case of distinguishing the modulation scheme of an analog terrestrial broadcast and the modulation scheme of a digital terrestrial broadcast, for example, the detection frequency of one of the detectors is set to the carrier frequency for the analog terrestrial broadcast, whilst the detection frequency of the other one is set to the center frequency of the IF signal. Hence, the modulation scheme can be readily identified based on the difference between signal levels detected by the two detector. Also, various modulation schemes, including those for analog terrestrial broadcast and digital terrestrial broadcast, can be distinguished.

The detecting circuit 21 of the present embodiment is connected to the mixing section 20 and identifies the modulation scheme of an incoming signal from the IF signal output of the mixing section 20. The configuration enables the modulation scheme identification in a relatively early stage in the signal path when compared with a conventional configuration in which the output of the mixing section is amplified before being fed to the detecting circuit and another conventional configuration in which the output of the mixing section is filtered before being fed to the detecting circuit. These factors allow for reduction in circuit size and power consumption. In addition, for example, the mixing section 20 and the detecting circuit 21 may be provided next to each other, and/or the mixing section 20 and the detecting circuit 21 may be integrated in a single chip. That allows for further reduction in size of the circuit containing the mixing section 20 and the detecting circuit 21, hence reduction in size of the complex IC 33, the tuning device 30, and the common multi-scheme receiving device 100. Furthermore, the IF signal output of the mixing section 20 is fed directly to the detecting circuit 21 where a modulation scheme identification is carried out. That configuration reduces the power consumption by the detecting circuit 21 over conventional configurations in which the IF signal output of the mixing section 20 is amplified before the modulation scheme identification is carried out.

In the present embodiment, the detection frequency of the detector 8 is set to the center frequency of the picture carrier, i.e., 58.75 MHz., and the detection frequency of the detector 7 is set to 57 MHz, to distinguish the terrestrial analog broadcast scheme and the terrestrial digital broadcast scheme. The settings are not the only possibility. They may be set to suitable values such that modulation schemes can be distinguished by comparing the difference between signal levels at the detection frequencies of the detectors to a predetermined threshold. For example, the detection frequencies of the detectors 7, 8 may be set so as to identify the modulation scheme of the incoming signal with either one of two modulation schemes by determining whether or not the difference between the signal level detected by one of the detectors and the signal level detected by the other detector is less than a predetermined threshold. When there is a need to identify the modulation scheme with one of three modulation schemes, at least three detectors may be provided so that the modulation scheme can be identified by mutually comparing the signal levels (or signal level difference) detected by the at least three detectors.

The detection frequencies of the detectors are preferably set to such values that the difference between the signal levels detected by the detectors is more than or equal to a predetermined value (for example, 6 db). The settings enable accurate identification of the modulation schemes.

If the modulation schemes of received signals contain a modulation scheme for an analog wave, the detection frequency of one of two detectors is preferably set to a frequency at which the signal level of the IF signal produced from an analog wave peaks (the center frequency of the picture carrier, the sound carrier, or the color carrier in the present embodiment) or a nearby frequency (for example, ±0.75 MHz) for more accurate identification of modulation schemes.

The color carrier varies greatly in signal level depending on video signals (for example, black and white video). Therefore, the detection frequency of one of the detectors is more preferably set to the center frequency of the IF signal produced from the picture or sound carrier.

In the case of terrestrial analog broadcast, it is always the picture carrier, among the carriers, that exhibits a maximum signal level (for example, in accordance with the standard employed in Japanese terrestrial broadcast, P/S≧6 db, P/C≧17 db, where P is the signal level of the picture carrier, S the signal level of the sound carrier, and C the signal level of the color carrier). To more reliably identify modulation schemes, the detection frequency of one of two detectors is more preferably set to the center frequency of the picture carrier. The signal level of the sound carrier differ from country to country and from region to region (according to the standards employed in broadcasting systems in individual countries or regions). If the detection frequency of one of the two detectors is set to the center frequency of the picture carrier, modulation schemes can be distinguished more reliably and in a more stable manner.

The detection frequency of the other detector is preferably set to the frequency at which the IF signal produced from an incoming analog broadcast signal takes a minimum signal level. The setting increases difference between the signal levels detected by the two detectors and enables accurate modulation scheme identification. In the example shown in FIGS. 3(a) and 4(a) the signal level of the terrestrial analog broadcast is a minimum at 57 MHz. The frequency at which the signal level takes a minimum is not in the neighborhood of 57 MHz.

The present embodiment has so far discussed primarily examples of the common multi-scheme receiving device for Japanese terrestrial television broadcast (terrestrial analog broadcast and terrestrial digital broadcast). This is by no means intended to be limiting the invention. The present invention is applicable to anything that has the feature that the difference between signal levels at a first frequency and a second frequency differs from one modulation scheme to the other at the frequencies of the incoming signal (or of the IF signal produced from the incoming signal).

For example, the same terrestrial analog or digital broadcast scheme may be used under different standards from country to country and from region to region. Naturally, the broadcast signal spectrum also varies. However, in those situations, the detecting circuit of the present embodiment is still capable of distinguishing different modulation schemes if the detection frequencies of the detectors are set to suitable values.

Combinations of incoming signal modulation schemes and examples of the detection frequency settings, f1, f2, for the detectors 7, 8 are shown in Table 1 below.

TABLE 1

| | | | Examples |
|---|---|---|---|
| Country | | | of |
| or | Broadcast | Broadcast | Detection |
| Region | Scheme 1 | Scheme 2 | Frequencies |
| Japan | NTSC-M | ISDB-T | f1 = 57 MHz, |
| | (National Television | (Integrated Services | f2 = 58.75 MHz |
| | Standards | Digital Broadcasting | |
| | Committee-M) | for Terrestrial) | |
| North | NTSC-M | 8 VSB/QAM | f1 = 44 MHz, |
| America | | (8 Vestigial Side | f2 = 45.75 MHz |
| | | Band/Quadrature | |
| | | Amplitude | |
| | | Modulation) | |
| Europe | PAL | DVB-T | f1 = 36 MHz, |
| | (Phase Alternation | (Digital Video | f2 = 38.9 MHz |
| | by Line) | Broadcasting for | |
| | | Terrestrial) | |
| Europe | PAL-L' | DVB-T | f1 = 36 MHz, |
| (France) | (Phase Alternation | | f2 = 33.4 MHz |
| | by Line-L') | | |

The present invention is applicable not only to structures which receive analog terrestrial broadcast and digital terrestrial broadcast, but also to structures which receive, for example, satellite television broadcast, cable television broadcast, and other kinds of television broadcast.

Incidentally, the Tokukai 2001-285752 technique, as mentioned earlier, has a problem that it cannot be used if the center frequency of the incoming signal differs much from the carrier frequency (if the carrier frequency is lower than the center frequency of the incoming signal and differs much from the center frequency of the incoming signal).

An example is the identification of the television broadcast schemes in Europe (France): the DVB-T standard (Digital Video Broadcasting for Terrestrial, OFDM modulation standard) and the PAL-L′ standard (Phase Alternation by Line-L′). See Table 1.

Assume that television is broadcast using these broadcast standards. The IF signal produced from the signal that is OFDM-modulated by DVB-T standard has a spectrum with a center frequency of 36.166 MHz and a bandwidth of 5.64 MHz which is substantially flat across that bandwidth. In contrast, the PAL-L′ standard uses an AM/FM modulation scheme. The modulated picture carrier frequency is 33.4 MHz. Therefore, the picture carrier in the IF signal produced by the PAL-L′ standard occupies very low frequencies in the frequency band of the IF signal produced by the DVB-T standard.

Applying the Tokukai 2001-285752 technique to the spectrum greatly reduces the accuracy in modulation scheme identification, because the technique uses a lowpass filter which removes signal components at carrier frequencies.

In contrast, in the present embodiment, the detection frequencies of the detectors are set to suitable values so that modulation schemes can be identified by comparing the difference between signal levels at the detection frequencies of the two detectors to a predetermined threshold. Therefore, even if the carrier frequencies are low, modulation schemes are properly identified.

The detecting circuit 21 of the present embodiment may be adapted to carry out a modulation scheme identification on the output of the mixing section converting an RF signal to an IF signal. According to the configuration, the modulation scheme of an incoming signal is identified using the IF signal output of the mixing section. Therefore, the mixing section and the detecting circuit can be disposed next to each other. That allows for reduction in size of the circuit containing the mixing section and the detecting circuit. Still referring to the same configuration, the IF signal output of the mixing section is fed directly to the detecting circuit where a modulation scheme identification is carried out. That configuration reduces the power consumption by the detecting circuit over conventional configurations in which the IF signal output of the mixing section is amplified before the modulation scheme identification is carried out.

The detecting circuit of the present invention is, to solve the problems, characterized in that it is contained in a common multi-scheme receiver for receiving a plurality of transmission signals with different modulation schemes, the detecting circuit identifying a modulation scheme of an incoming signal from an IF signal produced by frequency conversion of the incoming signal, the detecting circuit including: detectors having different detection frequencies, each detector detecting a signal level of the IF signal at the detection frequency thereof; and a comparator for identifying the modulation scheme of the incoming signal from the signal levels detected by the detectors.

According to the configuration, the detectors detect the signal level at different detection frequencies. The comparator identifies the modulation scheme of the incoming signal from a comparison of the detected signal levels. Accordingly, various modulation schemes are identified by simply setting the detection frequencies of the detectors in accordance with the modulation schemes of incoming signals.

There may be included a filter circuit, disposed before at least one of the detectors, for removing signal components away from the detection frequency of that detector.

According to the configuration, the filter circuit, disposed before the detector, can remove signal components away from the detection frequency of the particular detector. That improves the accuracy in the modulation scheme identification.

The comparator may be adapted to identify the modulation scheme of the incoming signal from a comparison of a difference between the signal levels detected by two of the detectors to a preset threshold.

According to the configuration, the modulation scheme of the incoming signal can be identified by comparing the difference between two signal levels at different detection frequencies to the threshold predetermined in accordance with the nature of the modulation schemes.

There may be included a filter circuit, disposed before at least one of the detectors, for removing signal components away from the detection frequency of that detector, the filter circuit having a center frequency equal to that detection frequency and a cutoff level exceeding the threshold in a bandwidth not exceeding twice a difference between the detection frequencies of the two detectors.

The configuration prevents the signal at the detection frequency of one of the detectors from affecting the detection of a signal level by the other detector at its detection frequency, thereby achieving more accurate modulation scheme identification.

At least one of the plurality of transmission signals may be a modulated analog broadcast signal, and at least one of the detectors may have a detection frequency equal to a carrier frequency for an IF signal produced by frequency conversion of the modulated analog broadcast signal.

The IF signal produced by frequency conversion of a modulated analog broadcast signal has a greater signal level at the carrier frequency than at other frequencies. According to the configuration, at least one of the detectors has a detection frequency equal to the carrier frequency for the IF signal produced by frequency conversion of the modulated analog broadcast signal. That enables modulation scheme identification using the above feature of analog broadcast. That achieves high accuracy in modulation scheme identification.

At least one of the detectors may have a detection frequency equal to a center frequency of frequencies of the IF signal.

In analog broadcast, the signal level at the carrier frequency always differs from the signal level at the center frequency of the IF signal. According to the configuration, modulation schemes are identified using the signal level at the carrier frequency for the IF signal and the signal level at the center frequency of the IF signal. That achieves higher accuracy in modulation scheme identification.

The modulation scheme identifying circuit of the present invention is, to solve the problems, characterized in that it is used in a common multi-scheme receiving device for receiving a plurality of transmission signals with different modulation schemes, the modulation scheme identifying circuit including: a mixing section for converting an incoming signal to an IF signal; and a detecting circuit, connected to the mixing section, for identifying a modulation scheme of the incoming signal from the IF signal output of the mixing section.

According to the configuration, the detecting circuit is connected to the mixing section. The configuration enables the modulation scheme identification in a relatively early stage in the signal path when compared with a conventional configuration in which the output of the mixing section is amplified before being fed to the detecting circuit and another conventional configuration in which the output of the mixing section is filtered before being fed to the detecting circuit. These factors allow for reduction in circuit size and power consumption. In addition, the IF signal output of the mixing section is fed directly to the detecting circuit where a modulation scheme identification is carried out. That configuration reduces the power consumption by the detecting circuit over conventional configurations in which the IF signal output of the mixing section is amplified before the modulation scheme identification is carried out.

The detecting circuit in the modulation scheme identifying circuit may be any one of the aforementioned detecting circuits, that is, a detecting circuit including: detectors having different detection frequencies, each detector detecting a signal level of the IF signal at the detection frequency thereof; and a comparator for identifying the modulation scheme of the incoming signal from the signal levels detected by the detectors.

The configuration allows for reduction in size of the circuit containing the mixing section and the detecting circuit, hence reduction in size of the modulation scheme identifying circuit. Various modulation schemes are identified.

The integrated circuit of the present invention is, to solve the problems, characterized in that it is used in a common multi-scheme receiving device for receiving a plurality of transmission signals with different modulation schemes and includes any one of the aforementioned modulation scheme identifying circuit.

According to the configuration, there is provided a modulation scheme identifying circuit. In other words, there are provided a mixing section and a detecting circuit connected to the mixing section. The configuration enables the modulation scheme identification in a relatively early stage in the signal path when compared with a conventional configuration in which the output of the mixing section is amplified before being fed to the detecting circuit and another conventional configuration in which the output of the mixing section is filtered before being fed to the detecting circuit. These factors allow for reduction in circuit size and power consumption. Furthermore, according to the configuration, the mixing section and the detecting circuit are provided on the same integrated circuit. That allows for further reduction in size of the circuit containing the mixing section and the detecting circuit. In addition, by integrating the mixing section and the detecting circuit into a single chip, the detecting circuit can be made smaller and cheaper. In addition, according to the configuration, the IF signal output of the mixing section is fed directly to the detecting circuit for a modulation scheme identification. That reduces the power consumption by the detecting circuit over conventional configurations in which the IF signal output of the mixing section is amplified before the modulation scheme identification is carried out.

The tuning device of the present invention is, to solve the problems, characterized in that it is contained in a common multi-scheme receiving device for receiving a plurality of transmission signals with different modulation schemes, the tuning device selecting a desired one of the plurality of transmission signals, the tuning device including the modulation scheme identifying circuit.

According to the configuration, there is provided a modulation scheme identifying circuit, that is, a mixing section and a detecting circuit connected to the mixing section. The configuration enables the modulation scheme identification in a relatively early stage in the signal path when compared with a conventional configuration in which the output of the mixing section is amplified before being fed to the detecting circuit and another conventional configuration in which the output of the mixing section is filtered before being fed to the detecting circuit. These factors allow for reduction in circuit size and power consumption. In addition, for example, the mixing section and the detecting circuit may be disposed next to each other, and/or the mixing section and the detecting circuit may be integrated in a single chip. That allows for further reduction in size of the circuit containing the mixing section and the detecting circuit, hence reduction in size of the tuning device. Furthermore, according to the configuration, the IF signal output of the mixing section is fed directly to the detecting circuit where a modulation scheme identification is carried out. That configuration reduces the power consumption by the detecting circuit over conventional configurations in which the IF signal output of the mixing section is amplified before the modulation scheme identification is carried out.

The common multi-scheme receiving device of the present invention is, to solve the problems, characterized in that it receives a plurality of transmission signals with different modulation schemes, the common multi-scheme receiving device including the modulation scheme identifying circuit.

According to the configuration, there is provided a modulation scheme identifying circuit, that is, a mixing section and a detecting circuit connected to the mixing section. The configuration enables the modulation scheme identification in a relatively early stage in the signal path when compared with a conventional configuration in which the output of the mixing section is amplified before being fed to the detecting circuit and another conventional configuration in which the output of the mixing section is filtered before being fed to the detecting circuit. These factors allow for reduction in circuit size and power consumption. In addition, for example, the mixing section and the detecting circuit may be disposed next to each other, and/or the mixing section and the detecting circuit may be integrated in a single chip. That allows for further reduction in size of the circuit containing the mixing section and the detecting circuit, hence reduction in size of the common multi-scheme receiving device. Furthermore, according to the configuration, the IF signal output of the mixing section is fed directly to the detecting circuit where a modulation scheme identification is carried out. That configuration reduces the power consumption by the detecting circuit over conventional configurations in which the IF signal output of the mixing section is amplified before the modulation scheme identification is carried out.

The common multi-scheme receiving device may include: demodulating circuits, each of which demodulates different modulated signals; and a control section for switching on/off the demodulating circuits based on an identification made by the detecting circuit.

According to the configuration, the demodulating circuits are switched on/off based on an identification made by the detecting circuit. The demodulating circuit for the demodulation of the modulated signal corresponding to the identification is switched on, and the other demodulating circuit(s) are switched off. That reduces the power consumption by the demodulating circuits.

The common multi-scheme receiving device may receive a television broadcast: for example, an analog terrestrial broadcast, a digital terrestrial broadcast, a satellite television broadcast, and a cable television broadcast.

The common multi-scheme receiving device may further include an external output section for external output of a signal demodulated in the demodulating circuits. In other words, the common multi-scheme receiving device may be a “set-top box” which demodulates signals in the demodulating circuits for external output.

The present invention is applicable to common multi-scheme receivers which receive a plurality of transmission signals with different modulation schemes, detecting circuits included in the common multi-scheme receivers to identify the modulation schemes of incoming signals, tuning devices including the detecting circuits, and the integrated circuits.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

What is claimed is:

1. A detecting circuit contained in a common multi-scheme receiver for receiving a plurality of transmission signals with different modulation schemes, said detecting circuit identifying a modulation scheme of an incoming signal from an IF signal produced by frequency conversion of the incoming signal, said detecting circuit comprising:
detectors having different detection frequencies, each detector detecting a signal level of the IF signal at the detection frequency thereof; and
a comparator for identifying the modulation scheme of the incoming signal from the signal levels detected by the detectors.

2. The detecting circuit of claim 1, further comprising: a filter circuit, disposed before at least one of the detectors, for removing signal components away from the detection frequency of that detector.

3. The detecting circuit of claim 1, wherein the comparator identifies the modulation scheme of the incoming signal from a comparison of a difference between the signal levels detected by two of the detectors to a preset threshold.

4. The detecting circuit of claim 3, further comprising: a filter circuit, disposed before at least one of the detectors, for removing signal components away from the detection frequency of that detector, the filter circuit having a center frequency equal to that detection frequency and a cutoff level exceeding the threshold in a bandwidth not exceeding twice a difference between the detection frequencies of the two detectors.

5. The detecting circuit of claim 1, wherein:
at least one of the plurality of transmission signals is a modulated analog broadcast signal; and
at least one of the detectors has a detection frequency equal to a carrier frequency for an IF signal produced by frequency conversion of the modulated analog broadcast signal.

6. The detecting circuit of claim 5, wherein:
at least one of the detectors has a detection frequency equal to a center frequency of frequencies of the IF signal.

7. A modulation scheme identifying circuit used in a common multi-scheme receiving device for receiving a plurality of transmission signals with different modulation schemes, said modulation scheme identifying circuit comprising:
a mixing section for converting an incoming signal to an IF signal; and
a detecting circuit, connected to the mixing section, for identifying a modulation scheme of the incoming signal from the IF signal output of the mixing section.

8. The modulation scheme identifying circuit of claim 7, wherein the detecting circuit is contained in a common multi-scheme receiver for receiving a plurality of transmission signals with different modulation schemes, the detecting circuit identifying a modulation scheme of an incoming signal from an IF signal produced by frequency conversion of the incoming signal, the detecting circuit including:
detectors having different detection frequencies, each detector detecting a signal level of the IF signal at the detection frequency thereof; and
a comparator for identifying the modulation scheme of the incoming signal from the signal levels detected by the detectors.

9. An integrated circuit used in a common multi-scheme receiving device for receiving a plurality of transmission signals with different modulation schemes, said integrated circuit comprising a modulation scheme identifying circuit used in a common multi-scheme receiving device for receiving a plurality of transmission signals with different modulation schemes, the modulation scheme identifying circuit including:
a mixing section for converting an incoming signal to an IF signal; and
a detecting circuit, connected to the mixing section, for identifying a modulation scheme of the incoming signal from the IF signal output of the mixing section.

10. A tuning device contained in a common multi-scheme receiving device for receiving a plurality of transmission signals with different modulation schemes, said tuning device selecting a desired one of the plurality of transmission signals, said tuning device comprising: a modulation scheme identifying circuit used in a common multi-scheme receiving device for receiving the plurality of transmission signals with different modulation schemes, the modulation scheme identifying circuit including:
a mixing section for converting an incoming signal to an IF signal; and
a detecting circuit, connected to the mixing section, for identifying a modulation scheme of the incoming signal from the IF signal output of the mixing section.

11. A common multi-scheme receiving device for receiving a plurality of transmission signals with different modulation schemes, said common multi-scheme receiving device comprising a modulation scheme identifying circuit including:
a mixing section for converting an incoming signal to an IF signal; and
a detecting circuit, connected to the mixing section, for identifying a modulation scheme of the incoming signal from the IF signal output of the mixing section.

12. The common multi-scheme receiving device of claim 11, further comprising:
demodulating circuits, each of which demodulates different modulated signals; and
a control section for switching on/off the demodulating circuits based on an identification made by the detecting circuit.

13. The common multi-scheme receiving device of claim 11, wherein the common multi-scheme receiving device receives a television broadcast.

14. The common multi-scheme receiving device of claim 12, further comprising an external output section for external output of a signal demodulated in the demodulating circuits.
